(19) United States
(12) Patent Application Publication
(10) Pub. No.: US 2025/0321015 A1
(43) Pub. Date: Oct. 16, 2025

(54) MACHINE ROOM FOR ACCOMMODATING IMMERSION COOLING ELECTRONIC SYSTEM AND CONTROL METHOD THEREOF

(71) Applicant: Wiwynn Corporation, New Taipei City (TW)

(72) Inventors: YU-CHING CHEN, New Taipei City (TW); JUI-PIN WANG, New Taipei City (TW); CHENG-LUNG CHEN, New Taipei City (TW); SHAO YEN, New Taipei City (TW)

(21) Appl. No.: 19/172,722

(22) Filed: Apr. 8, 2025

Related U.S. Application Data
(60) Provisional application No. 63/633,999, filed on Apr. 15, 2024.

(30) Foreign Application Priority Data
Mar. 28, 2025 (TW) 114112095

(51) Int. Cl. F24F 11/00; B25J 9/02; F24F 110/10; F24F 110/20; F24F 110/76; F24F 140/50; G05D 7/06; G05D 23/19; H05K 7/20

(52) U.S. Cl. CPC F24F 11/0001; G05D 7/0617; G05D 23/1917; B25J 9/026; F24F 2110/10; F24F 2110/20; F24F 2110/76; F24F 2140/50; H05K 7/20236

(57) ABSTRACT

a machine room for accommodating an immersion cooling electronic system includes a chamber, an exhaust device, a reservoir tank group and a control system. The exhaust device is disposed in the chamber and configured to exhaust gas out of the chamber. The reservoir tank group is located in the chamber and includes at least one liquid cooling tank and its cover. The at least one liquid cooling tank is configured to accommodate a coolant and at least one electronic device for at least partially immersing the at least one electronic device in the coolant, and the cover is movably disposed on the at least one liquid cooling tank to cover the corresponding at least one liquid cooling tank. The control system is electrically connected to the exhaust device and configured to adjust an exhaust volume of the exhaust device.

### CROSS-REFERENCE TO RELATED APPLICATIONS

This non-provisional application claims priority under 35 U.S.C. § 119(a) on Provisional Application No(s). 63/633,999 filed in U.S.A. on Apr. 15, 2024, and Patent Application No(s). 114112095 filed in Taiwan, R.O.C. on Mar. 28, 2025, the entire contents of which are hereby incorporated by reference.

### TECHNICAL FIELD

The disclosure provides a machine room for accommodating an immersion cooling electronic system and a control method thereof.

### BACKGROUND

As the performance of electronic devices, such as servers, improves, the amount of heat generated by these electronic devices during operation also increases. Immersion cooling involves immersing the electronic devices in the coolant in a tank, and heat generated by the operation of the electronic devices is removed through the phase change of the coolant from liquid to gas. Typically, the coolant is a non-conductive two-phase heat transfer medium with low boiling point.

When the electronic devices are moved in and out of the tank or undergo maintenance, the tank usually needs to be opened. However, once the tank is opened, the gaseous heat transfer medium escapes into the surrounding environment, affecting people located in that environment. In light of this, how to address the aforementioned issue is one of the topics in this field.

### SUMMARY

One embodiment of the disclosure provides a machine room for accommodating an immersion cooling electronic system. The machine room includes a chamber, an exhaust device, a reservoir tank group and a control system. The exhaust device is disposed in the chamber and configured to exhaust gas out of the chamber. The reservoir tank group is located in the chamber and includes at least one liquid cooling tank and its cover. The at least one liquid cooling tank is configured to accommodate a coolant and at least one electronic device for at least partially immersing the at least one electronic device in the coolant, and the cover is movably disposed on the at least one liquid cooling tank to cover the corresponding at least one liquid cooling tank. The control system is electrically connected to the exhaust device and configured to adjust an exhaust volume of the exhaust device.

Another embodiment of the disclosure provides a control method of a machine room for accommodating an immersion cooling electronic system. The control method includes placing, via a gripping device, at least one electronic device into at least one liquid cooling tank of a reservoir tank group, wherein a cover corresponding to the at least one liquid cooling tank is opened, and adjusting an exhaust volume of an exhaust device via a control system to exhaust gas out of a chamber where the reservoir tank group is located.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a machine room according to some embodiments of the disclosure;

FIG. 2 is a partial perspective view of a machine room according to some embodiments of the disclosure;

FIG. 3 is a block diagram of a machine room according to some embodiments of the disclosure;

FIG. 4 is a part of a flow chart of a control method of a machine room according to some embodiments of the disclosure;

FIG. 5 is a part of a flow chart of a control method of a machine room according to some embodiments of the disclosure; and

FIG. 6 is a part of a flow chart of a control method of a machine room according to some embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

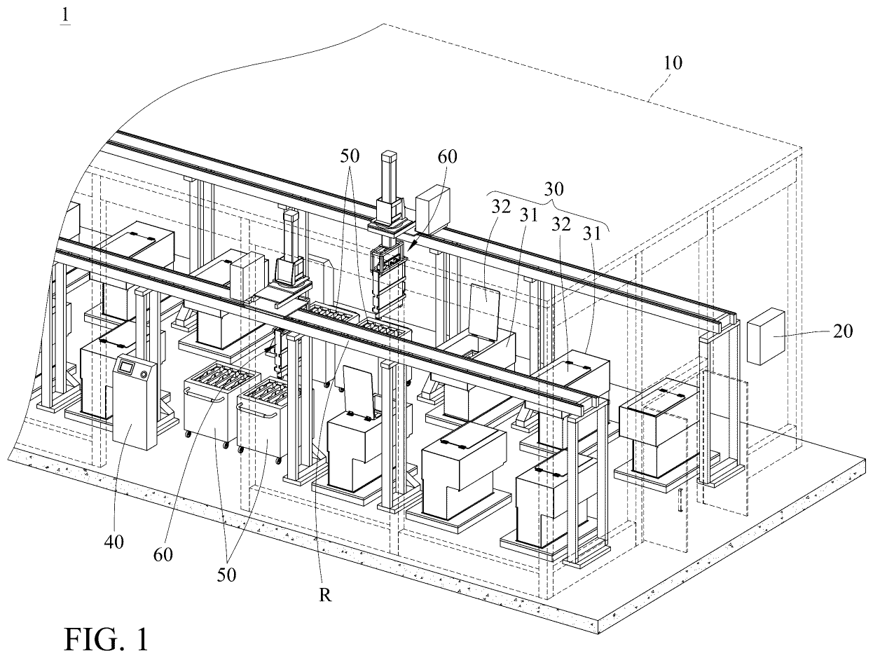

Referring to FIG. 1, FIG. 1 is a perspective view of a machine room 1 according to some embodiments of the disclosure. The structural features of FIG. 1 can be applied to other embodiments of the disclosure.

The machine room 1 is configured to accommodate an immersion cooling electronic system. The machine room 1 includes a chamber 10, an exhaust device 20, a reservoir tank group 30 and a control system 40.

In some embodiment, the chamber 10 includes walls and a roof. The walls may be provided with an entrance or an exit to allow operators or objects to enter or exit the chamber 10.

In some embodiments, the exhaust device 20 is disposed in the chamber 10, and the exhaust device 20 is configured to exhaust gas out of the chamber 10.

The reservoir tank group 30 is located in the chamber 10 and includes at least one liquid cooling tank 31 and its cover 32. In some embodiments, the reservoir tank group 30 may include a plurality of liquid cooling tanks and corresponding covers 32. The covers 32 are movably disposed on their corresponding liquid cooling tanks 31, and can be controlled to cover or uncover the liquid cooling tanks 31, thereby closing or opening internal spaces of the liquid cooling tanks 31.

The control system 40 is electrically connected to the exhaust device 20 (as shown in FIG. 1), and the control system 40 is configured to adjust the exhaust volume of the exhaust device 20.

In some embodiments, the control system 40 includes a control unit located in the chamber 10, but the disclosure is not limited thereto. In some embodiments, the control system may include a control unit located outside the chamber, such as a cloud server. In some embodiments, the control system may include on-premises server or virtual machine.

In some embodiments, the control system 40 is further electrically connected to the reservoir tank group 30, and the control system 40 is configured to adjust the exhaust volume of the exhaust device 20 based on an opening information of the covers 32 of the reservoir tank group 30. In some embodiments, when the control system 40 determines that the cover 32 is open, the control system 40 adjusts the exhaust volume of the exhaust device 20 to a maximum exhaust volume. In some embodiments, when the control system 40 determines that the cover 32 is closed, the control system 40 adjusts the exhaust volume of the exhaust device 20 to a predetermined exhaust volume, where the predetermined exhaust volume is lower than the maximum exhaust volume. For example, the predetermined exhaust volume may be 30% of the maximum exhaust volume.

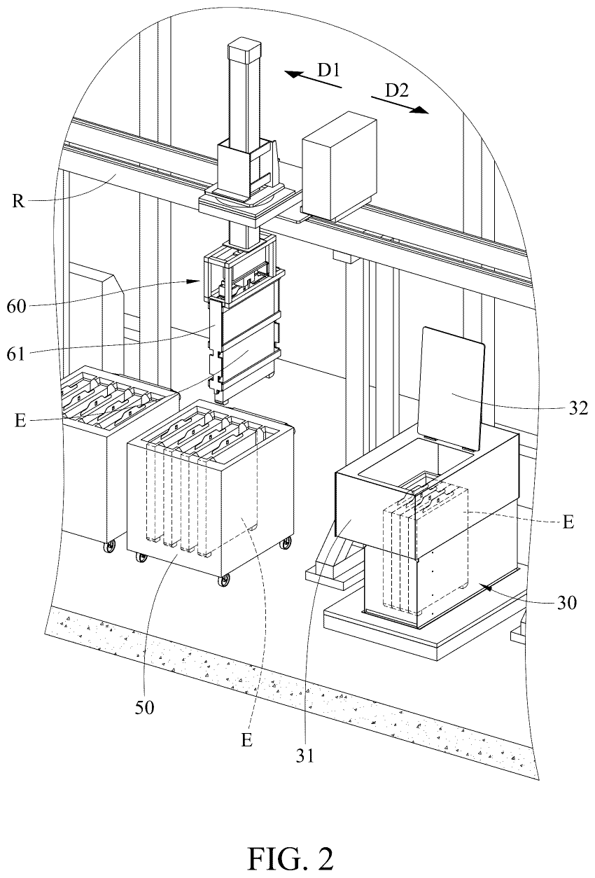

Referring to FIG. 2, FIG. 2 is a partial perspective view of the machine room 1 according to some embodiments of the disclosure. The structural features of FIG. 2 can be applied to other embodiments of the disclosure.

Each of the liquid cooling tanks 31 is configured to accommodate a coolant (not shown) and at least one electronic device E, allowing the at least one electronic device E to be at least partially immersed in the coolant. The coolant in the liquid cooling tank 31 can absorb heat generated during the operation of the electronic device E. The electronic device E, for example, may be a server. In some embodiments, the coolant in the liquid cooling tank 31 is a two-phase heat transfer medium with low boiling point, such as a fluorinated liquid. In some other embodiments, the coolant may be a low-temperature single-phase heat transfer medium.

In some embodiments, the machine room 1 further includes at least one transport device 50 and at least one gripping device 60. In some embodiments, the machine room 1 may include a plurality of transport devices 50 and a plurality of gripping devices 60. The transport device 50 may be an autonomous guided vehicle (AGV) or a manually operated cart. The transport device 50 is configured to transport the electronic device E. The gripping device 60, such as a robotic gripper, is configured to grip the electronic device E and place it into the liquid cooling tank 31. The control system 40 (as shown in FIG. 1) is electrically connected to the transport device 50 and the gripping device 60. The control system 40 is configured to adjust the opening and closing of the cover 32 and to assign tasks to the gripping device 60 for gripping the electronic device E, at least based on the quantity information of the electronic device E carried by the transport device 50.

In some embodiments, the gripping device 60 has a stabilizing module 61. The stabilizing module 61 is configured to stabilize the electronic device E being vertically lifted and horizontally moved via a gripper of the gripping device 60, thereby being able to precisely align with the AGV or the slot in the tank. For example, the stabilizing module 61 may limit the degree of freedom of the electronic device E in one direction when the gripping device 60 grips the electronic device E. In some embodiments, the said direction corresponds to a sliding direction D1 or D2 of the gripping device 60 mounted on a slide rail R. In the illustrated embodiment, the slide rail R is a part of a gantry frame. In the illustrated embodiment, the stabilizing module 61 comprises a retaining frame that defines a bottom opening, allowing the electronic device E (e.g., a single server) to pass through and enter an internal space enclosed by the retaining frame, where it is firmly supported laterally. In some embodiments, the inner side of the retaining frame may further include a guiding mechanism, such as wheels, to facilitate the server's entry into or exit from the internal space of the retaining frame.

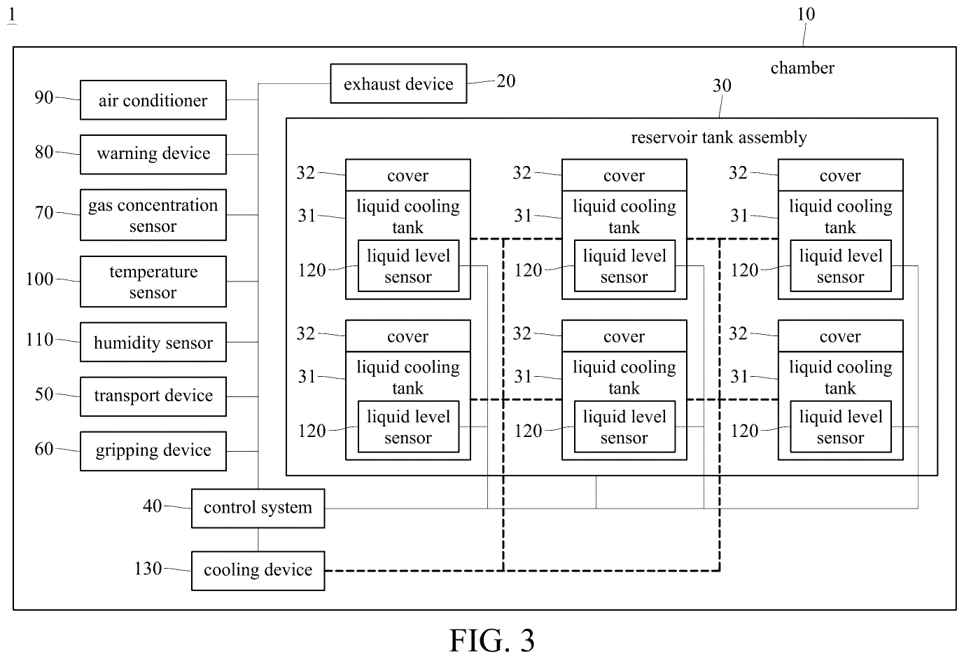

Referring to FIG. 3, FIG. 3 is a block diagram of the machine room 1 according to some embodiments of the disclosure. In FIG. 3, a solid line connecting two components indicates an electrical connection between them, meaning that signals can be transmitted between the two components; a dashed line connecting two components indicates that the components are in fluid communication (e.g., connected through pipelines), allowing fluid to flow between them.

In some embodiments, the machine room 1 may further include a gas concentration sensor 70. The gas concentration sensor 70 is configured to measure a gas concentration in the chamber 10. The control system 40 is electrically connected to the gas concentration sensor 70, and the control system 40 is configured to adjust the exhaust volume of the exhaust device 20 based on a concentration information generated by the gas concentration sensor 70. In some embodiments, the gas concentration sensor 70 is configured to measure an oxygen concentration. When the control system 40 determines that an actual oxygen concentration measured by the gas concentration sensor 70 is lower than a predetermined minimum oxygen concentration, the control system 40 increases the exhaust volume of the exhaust device 20. Conversely, when the control system 40 determines that the actual oxygen concentration measured by the gas concentration sensor 70 is higher than the predetermined minimum oxygen concentration, the control system 40 decreases the exhaust volume of the exhaust device 20 to a predetermined exhaust volume, which is lower than a maximum exhaust volume. For example, the predetermined exhaust volume may be 30% of the maximum exhaust volume.

In some embodiments, the machine room 1 may further include a warning device 80. The control system 40 is electrically connected to the warning device 80. When the control system 40 determines that the actual oxygen concentration measured by the gas concentration sensor 70 is lower than the predetermined minimum oxygen concentration, the control system 40 activates the warning device 80. In one embodiment, the warning device 80 may be an alarm light or a speaker.

In some embodiments, the machine room 1 may further include an air conditioner 90. The air conditioner 90 is disposed in the chamber 10 and electrically connected to the control system 40. In some embodiments, the machine room 1 may further include a temperature sensor 100. The temperature sensor 100 is configured to measure a temperature in the chamber 10. The control system 40 is electrically connected to the temperature sensor 100, and the control system 40 is configured to adjust a temperature in the chamber 10 via controlling the air conditioner 90 based on a temperature information generated by the temperature sensor 100. In some embodiments, the machine room 1 further includes a humidity sensor 110. The humidity sensor 110 is configured to measure a humidity in the chamber 10. The control system 40 is electrically connected to the humidity sensor 110, and the control system 40 is configured to adjust the temperature in the chamber 10 via controlling the air conditioner 90 based on a humidity information generated by the humidity sensor 110.

In some embodiments, the control system 40 is further configured to adjust a pressure in the chamber 10. The aforementioned pressure may be air pressure, which can be measured by a pressure sensor (not shown) electrically connected to the control system 40. The control system 40 may adjust the air pressure in the chamber 10 via controlling the air conditioner 90 or the exhaust device 20.

In some embodiments, the machine room 1 further includes a plurality of liquid level sensors 120. The liquid level sensors 120 are electrically connected to the control system 40. The liquid level sensors 120 are respectively disposed in the liquid cooling tanks 31, and the liquid level sensors 120 are configured to measure a liquid level of the coolant in the liquid cooling tanks 31.

In some embodiments, the machine room 1 may further include a cooling device 130. The cooling device 130 is connected to the liquid cooling tanks 31 via pipelines. The cooling device 130 is configured to cool the liquid cooling tanks 31. In some embodiments, the control system 40 is electrically connected to the cooling device 130. The control system 40 is configured to adjust a flow rate of the cooling device 130 based on power consumption of the liquid cooling tanks 31 or the quantity of electronic devices E (as shown in FIG. 2) in the liquid cooling tanks 31. In some embodiments, the cooling device 130 includes liquid pipelines disposed in the chamber and thermally coupled to the liquid cooling tanks 31. These liquid pipelines allow low-temperature liquid (e.g., water) to flow and exchange heat with the liquid cooling tanks 31, thereby cooling the liquid cooling tanks 31.

Next, the control method of the machine room 1 will be introduced. The control method includes placing, via the gripping device 60, the electronic device E into the liquid cooling tank 31, wherein the cover 32 corresponding to the liquid cooling tank 31 of the reservoir tank group 30 is opened. The control method also includes adjusting the exhaust volume of the exhaust device 20 via the control system 40 to exhaust gas out of the chamber 10 where the reservoir tank group 30 is located.

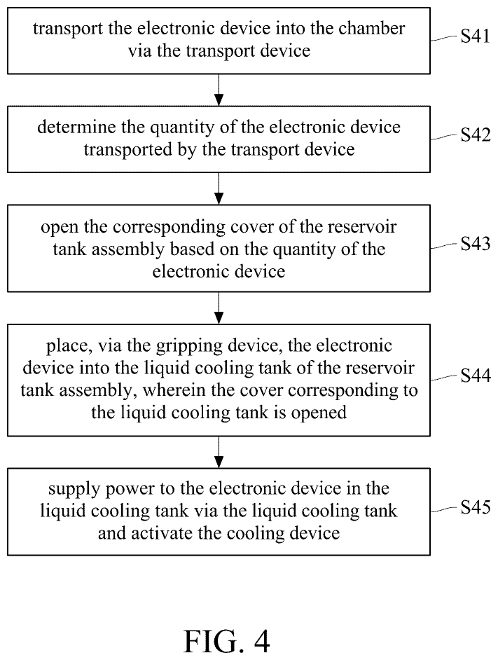

Then, referring to FIGS. 2 to 4, FIG. 4 is a part of a flow chart of the control method of the machine room 2 according to some embodiments of the disclosure.

In some embodiments, before the step of placing, via the gripping device 60, the electronic device E into the liquid cooling tank 31, wherein the cover 32 corresponding to the liquid cooling tank 31 of the reservoir tank group 30 is opened, the control method further includes steps S41-S43.

First, the step S41 is performed to transport the electronic device E into the chamber 10 via the transport device 50. Assuming that the transport device 50 is an AGV, when the electronic device E needs to be placed into the liquid cooling tank 31, the control system 40 drives the transport device 50 to transport the electronic device E carried by the transport device 50 to a specific position in chamber 10, such as a position reachable by the gripping device 60.

Next, the step S42 is performed to determine the quantity of the electronic device E transported by the transport device 50. For example, the transport device 50 is provided with a sensor (not shown) to measure the quantity of the electronic device E transported by the transport device 50. The transport device 50 will transmit this quantity information to the control system 40 via a signal. In this way, the control system 40 can obtain the quantity of electronic device E carried by the transport device 50.

Next, the step S43 is performed to open the corresponding cover 32 of the reservoir tank group 30 based on the quantity of the electronic device E. For example, if the transport device 50 is carrying two electronic devices E, and one of the liquid cooling tanks 31 currently has two available spaces, the control system 40 will drive the cover 32 corresponding to that liquid cooling tank 31 to open. On the other hand, if the transport device 50 is carrying two electronic devices E, and only two of the liquid cooling tanks 31 currently each have one available space, the control system 40 will drive the two covers 32 corresponding to the two liquid cooling tanks 31 to open.

Next, a step S44 is performed to place, via the gripping device 60, the electronic device E into the liquid cooling tank 31 of the reservoir tank group 30, wherein the cover 32 corresponding to the liquid cooling tank 31 is opened. For example, after the cover 32 is opened, the control system 40 drives the gripping device 60 to move above the transport device 50. Then, the gripping device 60 goes down to grip the electronic device E. After the gripping device 60 has gripped the electronic device E, it goes up and then moves above the liquid cooling tank 31 corresponding to the opened cover 32. Then, the gripping device 60 goes down to place the electronic device E into the liquid cooling tank 31. Once the control system 40 receives a signal from the gripping device 60 indicating that the electronic device E has been placed into the liquid cooling tank 31, the control system 40 drives the cover 32 corresponding to the liquid cooling tank 31 to close.

Next, a step S45 is performed to supply power to the electronic device E in the liquid cooling tank 31 via the liquid cooling tank 31 and activate the cooling device 130.

For example, after the control system 40 determines, based on a signal returned from the gripping device 60, indicating that the electronic device E has been placed in the liquid cooling tank 31, and based on a signal returned from the reservoir tank group 30, indicating that the electronic device E is properly installed and the cover 32 is closed, the control system 40 drives the liquid cooling tank 31 of the reservoir tank group 30 to supply power to the electronic device E to enable its operation, thus starting the performing of the electronic device E. In addition, the control system 40 drives the cooling device 130 to operate to drive low-temperature liquid (e.g., water) to flow and exchange heat with the liquid cooling tanks 31 so as to absorb heat generated by the electronic device E during its operation.

In some embodiments, the control system 40 may adjust a flow rate of the cooling device 130 for cooling the liquid cooling tank 31 based on the power consumption of the liquid cooling tank 31 or the quantity of the electronic device E in the liquid cooling tank 31, in order to achieve energy-saving effects.

In some embodiments, the control method may further include measuring the liquid level of the liquid cooling tank 31. If the liquid level of the liquid cooling tank 31 is lower than a predetermined liquid level, a warning signal is generated. For example, the control system 40 determines the liquid level in the liquid cooling tank 31 based on the information generated by the liquid level sensor 120. When the control system 40 determines that the liquid level of the liquid cooling tank 31 is lower than the predetermined liquid level (indicating insufficient coolant in the liquid cooling tank 31), the control system 40 generate a warning signal to alert the operators.

When the electronic device E has completed its task and needs to be removed from the liquid cooling tank 31, the control system 40 stops supplying power to the electronic device E via the liquid cooling tank 31. Then, the control system 40 drives the cover 32 corresponding to the liquid cooling tank 31 to open, and then drives the gripping device 60 to move above the liquid cooling tank 31. The gripping device 60 then goes down to grip the electronic device E in the liquid cooling tank 31 so as to lift the electronic device E into the stabilizing module 61. Afterwards, the gripping device 60 goes up and moves across neighboring liquid cooling tanks 31 along the sliding rail R then arrive at a position above the transport device 50. Next, the gripping device 60 goes down to place the electronic device E into the transport device 50. When the control system 40 receives a signal from the gripping device 60 indicating that the electronic device E has been placed into the transport device 50, the control system 40 drives the cover 32 corresponding to the liquid cooling tank 31 to close.

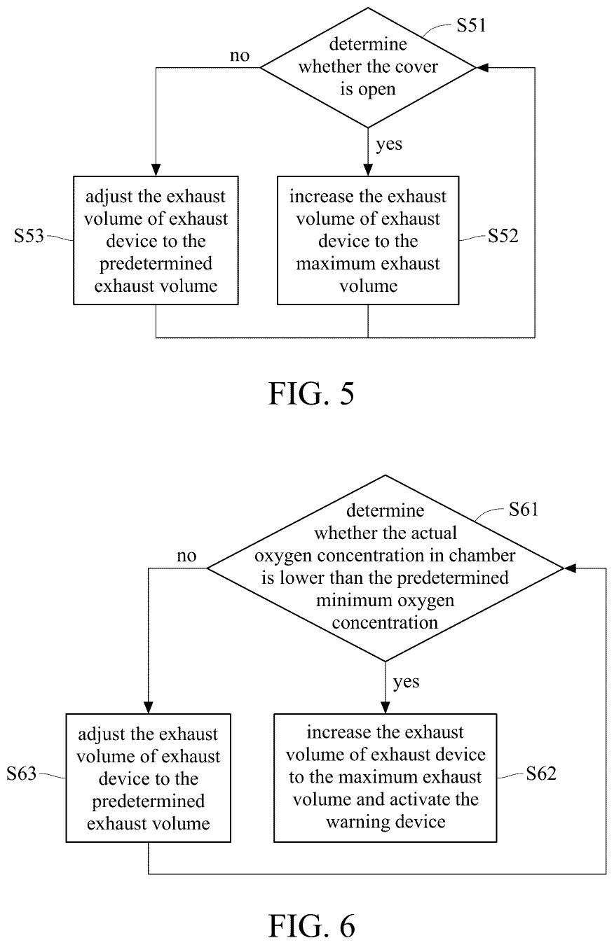

In the control method described above, the step of adjusting the exhaust volume of the exhaust device 20 via the control system 40 to exhaust gas out of the chamber 10 where the reservoir tank group 30 is located, includes receiving the opening information of the cover 32 of the reservoir tank group 30 in the chamber 10, and adjusting the exhaust volume of the exhaust device 20 disposed in the chamber 10 based on the opening information. Referring to FIGS. 2, 3 and 5, FIG. 5 is a part of a flow chart of the control method of the machine room 1 according to some embodiments of the disclosure. In some embodiments, the aforementioned steps include steps S51-S53.

The step S51 is performed to determine whether the cover 32 is open. If yes, the step S52 is performed to increase the exhaust volume of exhaust device 20 to the maximum exhaust volume. For example, the control system 40 continuously monitors whether the cover 32 is open. As mentioned above, once the cover 32 is opened, the reservoir tank group 30 sends a signal indicating the opening of the cover 32 to control system 40. Based on this signal, the control system 40 can determine that the cover 32 is in the open state. After the cover 32 is opened, the coolant in the liquid cooling tank 31, which has vaporized due to heat absorption, may escape into the chamber 10 where the liquid cooling tank 31 is located. At this moment, the control system 40 will increase the exhaust volume of exhaust device 20 to the maximum exhaust volume in order to accelerate the discharge of the coolant in gas state out of the chamber 10. This could prevent adverse effects on operators in the chamber 10 (e.g., prevent the operators from unintentionally inhaling excessive amounts of this gas).

It should be noted that after the cover 32 is opened, the exhaust volume of exhaust device 20 is not limited to being increased to the maximum exhaust volume. In some other embodiments, after the cover is opened, the exhaust volume of the exhaust device may be merely adjusted to be greater than the exhaust volume before the cover was opened.

After step S52, the step S51 is performed again to determine whether the cover 32 is opened. If not, the step S53 is performed to adjust the exhaust volume of exhaust device 20 to the predetermined exhaust volume, where the predetermined exhaust volume is lower than the maximum exhaust volume. For example, after the control system 40 receives a signal from the reservoir tank group 30 indicating that the cover 32 is closed, the cover 32 is determined to be properly closed. Therefore, the control system 40 will reduce the exhaust volume of exhaust device 20.

Then, referring to FIGS. 3 and 6, FIG. 6 is a part of a flow chart of the control method of the machine room 1 according to some embodiments of the disclosure.

In some embodiments, the control method described above may further include steps S61-S63. The step S61 is performed to determine whether the actual oxygen concentration in chamber 10 is lower than the predetermined minimum oxygen concentration. For example, the control system 40 determines whether the oxygen concentration measured by the gas concentration sensor 70 is lower than the predetermined minimum oxygen concentration. If yes, the step S62 is performed to increase the exhaust volume of exhaust device 20 to the maximum exhaust volume and activate the warning device 80. This helps reduce the concentration of gas escaping from the reservoir tank group 30, thereby increasing the oxygen concentration in chamber 10, while also alerting the operators. On the other hand, if no, the step S63 is performed to adjust the exhaust volume of exhaust device 20 to the predetermined exhaust volume, which is smaller than the maximum exhaust volume.

It should be noted that the gas concentration sensor 70 is not limited to measuring the oxygen concentration. In some other embodiments, the gas concentration sensor may be configured to measure the concentration of the gaseous coolant. In this case, the control method would be modified to determine whether the concentration of gaseous coolant in the chamber is higher than a predetermined maximum concentration.

It should be noted that the steps S51-S53 and S61-S63 are optional steps. In some other embodiments, steps S51-S53 may be omitted, and/or steps S61-S63 may be omitted. In embodiments where the steps S61-S63 are omitted, the gas concentration sensor 70 and warning device 80 may also be omitted.

In some embodiments, the control method may further include measuring a temperature information in the chamber 10 and adjusting the temperature in the chamber 10 via controlling the air conditioner 90 based on the temperature information. In some embodiments, the control method may also include measuring the humidity information in the chamber 10 and adjusting the temperature in the chamber 10 via controlling the air conditioner 90 based on the humidity information. For example, the control system 40 will determine, based on the values measured by the temperature sensor 100 and the humidity sensor 110, whether the temperature and the humidity in the chamber 10 need to be adjusted. This allows the temperature and the humidity in the chamber 10 to be controlled at set values, preventing the temperature and the humidity from affecting the operation of the electronic device E.

It should be noted that the aforementioned air conditioner 90, temperature sensor 100, humidity sensor 110, liquid level sensor 120, transport device 50, gripping device 60, and cooling device 130 are optional components and may be omitted in some other embodiments. Accordingly, the steps in the control method corresponding to these components may also be omitted.

According to the machine room for accommodating the immersion cooling electronic system and the control method thereof disclosed in the above embodiments, the chamber of the machine room is provided with the exhaust device, and the control system is electrically connected to the exhaust device and configured to adjust the exhaust volume of the exhaust device to exhaust gas dissipated from the reservoir tank group out of the chamber. In this way, it can prevent the operators in the chamber from being affected by such gas.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A machine room for accommodating an immersion cooling electronic system, comprising:
a chamber;
an exhaust device, disposed in the chamber and configured to exhaust gas out of the chamber;
a reservoir tank group, located in the chamber and comprising at least one liquid cooling tank and its cover, wherein the at least one liquid cooling tank is configured to accommodate a coolant and at least one electronic device for at least partially immersing the at least one electronic device in the coolant, and the cover is movably disposed on the at least one liquid cooling tank to cover the corresponding at least one liquid cooling tank; and
a control system, electrically connected to the exhaust device and configured to adjust an exhaust volume of the exhaust device.

2. The machine room according to claim 1, wherein the control system is further electrically connected to the reservoir tank group, and the control system is configured to adjust the exhaust volume of the exhaust device based on an opening information of the cover of the reservoir tank group.

3. The machine room according to claim 1, further comprising a gas concentration sensor, wherein the gas concentration sensor is configured to measure a gas concentration in the chamber, the control system is electrically connected to the gas concentration sensor, and the control system is configured to adjust the exhaust volume of the exhaust device based on a sensing information generated by the gas concentration sensor.

4. The machine room according to claim 3, wherein the gas concentration sensor is configured to measure an oxygen concentration; when the control system determines that an actual oxygen concentration measured by the gas concentration sensor is lower than a predetermined minimum oxygen concentration, the control system adjusts the exhaust volume of the exhaust device to a maximum exhaust volume.

5. The machine room according to claim 4, wherein when the control system determines that the actual oxygen concentration measured by the gas concentration sensor is higher than the predetermined minimum oxygen concentration, the control system adjusts the exhaust volume of the exhaust device to a predetermined exhaust volume, which is lower than the maximum exhaust volume.

6. The machine room according to claim 2, wherein when the control system determines that the cover is opened, the control system adjusts the exhaust volume of the exhaust device to a maximum exhaust volume.

7. The machine room according to claim 6, wherein when the control system determines that the cover is closed, the control system adjusts the exhaust volume of the exhaust device to a predetermined exhaust volume, which is lower than the maximum exhaust volume.

8. The machine room according to claim 4, further comprising a warning device, wherein the control system is electrically connected to the warning device; when the control system determines that the actual oxygen concentration measured by the gas concentration sensor is lower than the predetermined minimum oxygen concentration, the control system is configured to activate the warning device.

9. The machine room according to claim 1, further comprising an air conditioner disposed in the chamber.

10. The machine room according to claim 9, further comprising a temperature sensor, wherein the temperature sensor is configured to measure a temperature in the chamber, the control system is electrically connected to the temperature sensor, and the control system is configured to control the air conditioner so as to adjust a temperature in the chamber based on a sensing information generated by the temperature sensor.

11. The machine room according to claim 9, further comprising a humidity sensor, wherein the humidity sensor is configured to measure a humidity in the chamber, the control system is electrically connected to the humidity sensor, and the control system is configured to control the air conditioner so as to adjust a temperature in the chamber based on a sensing information generated by the humidity sensor.

12. The machine room according to claim 1, further comprising at least one liquid level sensor, wherein the liquid level sensor is disposed in the at least one liquid cooling tank, and the liquid level sensor is configured to measure a liquid level of the coolant in the at least one liquid cooling tank.

13. The machine room according to claim 1, further comprising at least one transport device and at least one gripping device, wherein the at least one transport device is configured to transport the at least one electronic device, the at least one gripping device is configured to grip and place the at least one electronic device into the at least one liquid cooling tank, the control system is electrically connected to the at least one transport device and the at least one gripping device, and the control system is configured to adjust opening or closing of the cover at least based on a quantity information of the at least one electronic device carried by the at least one transport device.

14. The machine room according to claim 13, wherein the at least one gripping device has a stabilizing module, the stabilizing module is configured to limit degrees of freedom of the at least one electronic device in one direction when the at least one gripping device grips the at least one electronic device.

15. The machine room according to claim 1, further comprising a cooling device configured to cool the at least one liquid cooling tank.

16. The machine room according to claim 15, wherein the control system is configured to adjust a flow rate of the cooling device based on a power consumption of the at least one liquid cooling tank or a quantity of at least one electronic device in the at least one liquid cooling tank.

17. The machine room according to claim 1, wherein the coolant in the at least one liquid cooling tank is a two-phase heat transfer medium with low boiling point.

18. The machine room according to claim 1, wherein the control system is further configured to adjust a pressure in the chamber.

19. A control method of a machine room for accommodating an immersion cooling electronic system, comprising:
placing, via a gripping device, at least one electronic device into at least one liquid cooling tank of a reservoir tank group, wherein a cover corresponding to the at least one liquid cooling tank is opened; and
adjusting an exhaust volume of an exhaust device via a control system to exhaust gas out of a chamber where the reservoir tank group is located.

20. The control method according to claim 19, further comprising:
receiving an opening information of the cover of the reservoir tank group in the chamber; and
adjusting the exhaust volume of the exhaust device disposed in the chamber based on the opening information.

21. The control method according to claim 20, before the step of receiving the opening information of the cover of the reservoir tank group in the chamber, further comprising:
transporting the at least one electronic device into the chamber via a transport device;
determining a quantity of the at least one electronic device carried by the transport device; and
opening the cover corresponding to the at least one liquid cooling tank based on the quantity of the at least one electronic device.

22. The control method according to claim 19, after the step of placing, via the gripping device, the at least one electronic device into the at least one liquid cooling tank of the reservoir tank group, further comprising:
supplying power to the at least one electronic device in the at least one liquid cooling tank via the at least one liquid cooling tank.

23. The control method according to claim 20, wherein the step of receiving the opening information of the cover of the reservoir tank group in the chamber and adjusting the exhaust volume of the exhaust device disposed in the chamber based on the at least one opening information further comprises:
determining whether the cover is opened;
if yes, adjusting the exhaust volume of the exhaust device to a maximum exhaust volume; and
if no, adjusting the exhaust volume of the exhaust device to a predetermined exhaust volume, wherein the predetermined exhaust volume is lower than the maximum exhaust volume.

24. The control method according to claim 19, further comprising:
determining whether an actual oxygen concentration in the chamber is lower than a predetermined minimum oxygen concentration;
if yes, adjusting the exhaust volume of the exhaust device to a maximum exhaust volume; and
if no, adjusting the exhaust volume of the exhaust device to a predetermined exhaust volume, wherein the predetermined exhaust volume is lower than the maximum exhaust volume.

25. The control method according to claim 19, further comprising:
measuring a temperature information in the chamber; and
controlling an air conditioner so as to adjusting a temperature in the chamber based on the temperature information.

26. The control method according to claim 19, further comprising:
measuring a humidity information in the chamber; and
controlling an air conditioner so as to adjusting a temperature in the chamber based on the humidity information.

27. The control method according to claim 19, further comprising:
measuring a liquid level in the at least one liquid cooling tank; and
generating a warning signal when the liquid level of the at least one liquid cooling tank is lower than a predetermined liquid level.

28. The control method according to claim 19, further comprising:
adjusting a flow rate of a cooling device for cooling the at least one liquid cooling tank based on a power consumption of the at least one liquid cooling tank or a quantity of the at least one electronic device in the at least one liquid cooling tank.
